(19) United States
(12) Patent Application Publication
(10) Pub. No.: US 2026/0334333 A1
(43) Pub. Date: Oct. 22, 2026

(54) SEMICONDUCTOR DEVICE

(71) Applicant: Samsung Electronics Co., Ltd., Suwon-si (KR)

(72) Inventor: Jeon Il Lee, Suwon-si (KR)

(21) Appl. No.: 19/565,816

(22) Filed: Mar. 13, 2026

(30) Foreign Application Priority Data
Apr. 16, 2025 (KR) 10-2025-0049239

(51) Int. Cl. H10W 90/20; H10W 20/00; H10W 20/20; H10W 20/42; H10W 90/00; H10W 90/26; H10B 80/00; H10D 80/30

(52) U.S. Cl. CPC H10W 90/297; H10W 20/0253; H10W 20/2134; H10W 20/421; H10W 90/26; H10W 90/792; H10B 80/00; H10D 80/30

(57) ABSTRACT

A semiconductor device includes a logic die, a first through via extending into at least a portion of the logic die, an upper pad on an upper surface of the logic die, a lower pad below a lower surface of the logic die and electrically connected to the first through via, and a plurality of memory dies stacked on the logic die, wherein the logic die includes, a first substrate including a first surface and a second surface opposite to the first surface, a first transistor on the first surface of the first substrate, a second substrate including a third surface and a fourth surface facing the first surface of the first substrate, a second transistor on the third surface of the second substrate, and an internal through via extending into the second substrate, wherein the first transistor and the second transistor are connected through the internal through via.

### CROSS-REFERENCE TO RELATED APPLICATIONS

This application claims priority to Korean Patent Application No. 10-2025-0049239, filed in the Korean Intellectual Property Office on Apr. 16, 2025, the entire contents of which are incorporated herein by reference.

### BACKGROUND

Higher performance and/or larger capacity may be required for semiconductor packages mounted in electronic devices. Accordingly, development of semiconductor packages including a plurality of dies has been undertaken, and signals transmitted and received among the plurality of dies have become increasingly complicated. For example, the semiconductor package may be implemented as a high bandwidth memory (HBM).

### SUMMARY

The present disclosure relates to a semiconductor device.

Aspects of the present disclosure provide a semiconductor device having improved electrical characteristics and integration density.

Aspects of the present disclosure provide a method of manufacturing a semiconductor device having improved electrical characteristics and integration density.

According to some embodiments of the present disclosure, a semiconductor device may a logic die; a first through via extending into at least a portion of the logic die; an upper pad on an upper surface of the logic die; a lower pad below a lower surface of the logic die and electrically connected to the first through via; and a plurality of memory dies stacked on the logic die, wherein the logic die comprises: a first substrate comprising a first surface and a second surface opposite to the first surface; a first transistor on the first surface of the first substrate; a second substrate comprising: a third surface, and a fourth surface opposite to the third surface and facing the first surface of the first substrate; a second transistor on the third surface of the second substrate; and an internal through via extending into the second substrate, wherein the first transistor and the second transistor are connected through the internal through via.

According to some embodiments of the present disclosure, a semiconductor device may include a first substrate comprising a first surface and a second surface opposite to the first surface; a first transistor on the first surface of the first substrate and comprising a first source/drain pattern and a second source/drain pattern; a first power line electrically connected to the first source/drain pattern, wherein the first power line is below the second surface of the first substrate; a second substrate comprising: a third surface, and a fourth surface opposite to the third surface and facing the first surface of the first substrate; a second transistor on the third surface of the second substrate and comprising a third source/drain pattern and a fourth source/drain pattern; a second power line electrically connected to the third source/drain pattern and below the fourth surface of the second substrate; a plurality of through via extending in a direction perpendicular to the first surface of the first substrate and extending into each of the first substrate and the second substrate; and a first internal through via extending into the second substrate, wherein the first transistor and the second transistor are electrically connected through the first internal through via.

According to some embodiments of the present disclosure, a semiconductor device may include a first substrate comprising a first surface and a second surface opposite to the first surface; a first transistor on the first surface of the first substrate and comprising a first source/drain pattern and a second source/drain pattern; a first power line electrically connected to the first source/drain pattern and below the second surface of the first substrate; a second substrate comprising: a third surface, and a fourth surface opposite to the third surface and facing the first surface of the first substrate; a second transistor on the third surface of the second substrate and comprising a third source/drain pattern and a fourth source/drain pattern; a first internal through via extending into the second substrate, wherein the second source/drain pattern of the first transistor and the fourth source/drain pattern of the second transistor are electrically connected through the first internal through via; an interlayer insulating layer below the second surface of the first substrate; a lower pad below a lower surface of the interlayer insulating layer; and a first wiring structure in the interlayer insulating layer and electrically connected to the first power line and the lower pad.

According to some embodiments of the present disclosure, by forming the first transistor and the second transistor in a single die and arranging an internal through via connecting the first transistor and the second transistor, a signal path from the first transistor to the second transistor may be shortened. Signal transmission and reception efficiency from the first transistor to the second transistor may be improved.

According to some embodiments of the present disclosure, by forming the first transistor disposed on the first substrate and the second transistor disposed on the second substrate in a single die, thickness of the semiconductor device may be reduced and integration density may be improved.

### BRIEF DESCRIPTION OF THE DRAWINGS

The above and other embodiments and features of the present disclosure will become more apparent by describing in detail example embodiments thereof with reference to the attached drawings, in which:

FIG. 1 illustrates a semiconductor device according to some embodiments of the present disclosure;

FIG. 2 is a cross-sectional view illustrating a semiconductor device according to some embodiments of the present disclosure;

FIGS. 3 to 5 illustrate semiconductor devices according to some embodiments of the present disclosure;

FIG. 6 is a cross-sectional view illustrating a semiconductor device according to some embodiments of the present disclosure;

FIG. 7 is a cross-sectional view illustrating a semiconductor device according to some embodiments of the present disclosure;

FIG. 8 is a view illustrating a semiconductor device according to some embodiments of the present disclosure;

FIG. 9 is a view illustrating a semiconductor device according to some embodiments of the present disclosure;

FIG. 10 is a view illustrating a semiconductor device according to some embodiments of the present disclosure;

FIG. 11 is a view illustrating a semiconductor package according to some embodiments of the present disclosure;

FIG. 12 is a view illustrating a semiconductor package according to some embodiments of the present disclosure;

FIGS. 13-18 are views illustrating methods of manufacturing a semiconductor device according to some embodiments of the present disclosure;

FIGS. 19-23 are views illustrating methods of manufacturing a semiconductor device according to some embodiments of the present disclosure;

FIGS. 24-28 are views illustrating methods of manufacturing a semiconductor device according to some embodiments of the present disclosure.

### DETAILED DESCRIPTION

In the present disclosure, the terms “upper,” “lower,” “upper surface,” and “lower surface” are used for convenience of description and are not limiting. The terms “upper,” “lower,” “upper surface,” and “lower surface” are described with respect to the drawings, and if the drawings are rotated, the terms designating upper and lower relationships may change accordingly.

Although “first,” “second,” and like terms are used to describe various elements or components in the present disclosure, the elements or components are not limited by these terms. These terms are used only to distinguish one element or component from another element or component. Within the technical spirit of the present disclosure, the first element or component may be the second element or component.

Hereinafter, with reference to the drawings, semiconductor devices and methods of manufacturing the same according to some embodiments of the present disclosure will be described in detail.

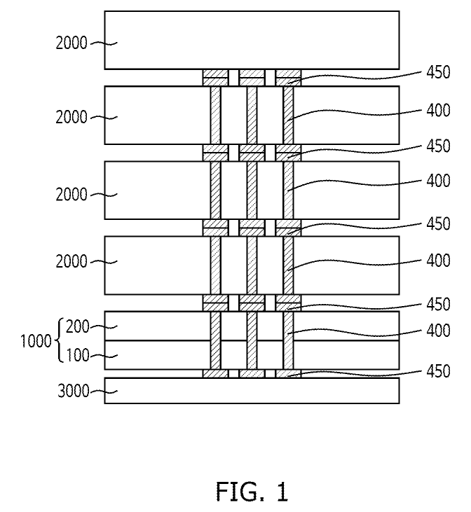

FIG. 1 illustrates a semiconductor device according to some embodiments of the present disclosure.

Referring to FIG. 1, the semiconductor device according to some embodiments may include an interposer 3000, a logic die 1000, a plurality of memory dies 2000, a plurality of through vias 400, and a plurality of pads 450.

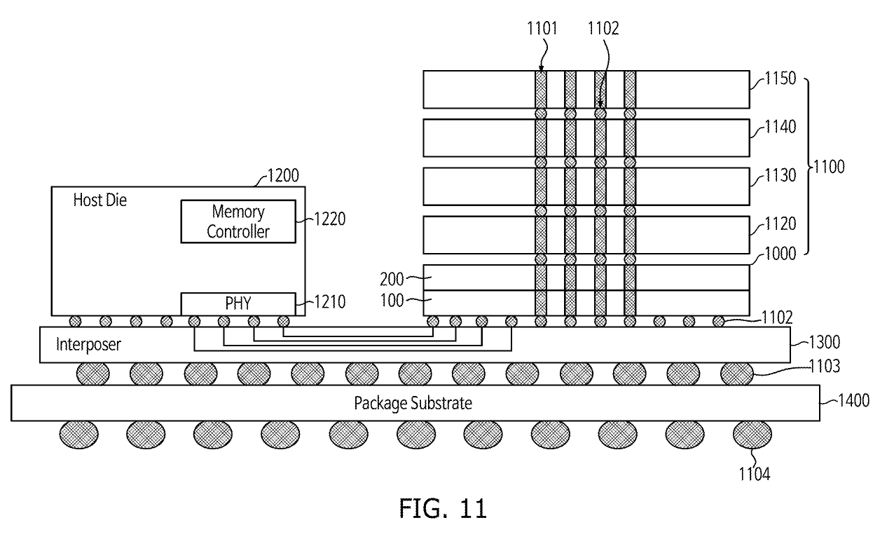

The interposer 3000 may connect the logic die 1000 to a host die (for example, the host die 1200 of FIG. 11) and may also connect the plurality of memory dies 2000 to the host die. The plurality of through vias 400 and the plurality of pads 450 may be electrically connected between the interposer 3000 and the logic die 1000 and between the interposer 3000 and the plurality of memory dies 2000. In the present disclosure, the phrase that one configuration is connected to another configuration may include physical connection and/or electrical connection. In some embodiments, the phrase that one configuration is electrically connected to another configuration may include direct electrical connection or indirect electrical connection through yet another configuration interposed between the configurations.

The logic die 1000 may be stacked on the interposer 3000. The logic die 1000 may be electrically connected to the interposer 3000. The logic die 1000 may transmit and receive signals to and from the host die through the interposer 3000. The logic die 1000 may transmit and receive signals to and from the plurality of memory dies 2000 through the plurality of through vias 400 and the plurality of pads 450.

The logic die 1000 may include a plurality of semiconductor structures. For example, the logic die 1000 may include a first semiconductor structure 100 and a second semiconductor structure 200. The first semiconductor structure 100 and the second semiconductor structure 200 may include different integrated circuits. A detailed structure of the logic die 1000 will be described later.

The plurality of memory dies 2000 may be stacked on the logic die 1000. Each memory die 2000 may include a memory device layer. The integrated circuit of the memory device layer of each memory die 2000 may include volatile memory devices such as dynamic random access memory (DRAM) and static random access memory (SRAM) and nonvolatile memory devices such as phase-change random access memory (PRAM), magnetoresistive random access memory (MRAM), resistive random access memory (ReRAM), and flash memory. For example, by including a plurality of channels each having an independent interface, the plurality of memory dies 2000 may constitute a high bandwidth memory (HBM) type memory device having an increased bandwidth.

As the number of the plurality of memory dies 2000 increases, performance (e.g., bandwidth and storage capacity) of the memory device may be further enhanced. Although the number of memory dies 2000 stacked on the logic die 1000 is illustrated as four, the present disclosure is not limited thereto.

The plurality of through vias 400 may penetrate the logic die 1000 and the plurality of memory dies 2000. For example, each through via 400 may penetrate at least part of the logic die 1000. Each through via 400 may penetrate at least part of each memory die 2000. In some embodiments, the plurality of through vias 400 may not be disposed in the memory die 2000 positioned at the uppermost part among the plurality of memory dies 2000.

The plurality of pads 450 may be disposed at ends of the plurality of through vias 400. For example, the plurality of pads 450 may be disposed at both ends of the plurality of through vias 400. The plurality of pads 450 may be electrically connected to the plurality of through vias 400. For example, connection may be made by a wiring structure between the plurality of pads 450 and the plurality of through vias 400. However, the present disclosure is not limited thereto. For example, the plurality of pads 450 may be directly connected to the plurality of through vias 400.

The plurality of through vias 400 and the plurality of pads 450 may be used as signal paths among components. For example, the plurality of through vias 400 and the plurality of pads 450 may be used as signal paths among the plurality of memory dies 2000, the logic die 1000, and the interposer 3000.

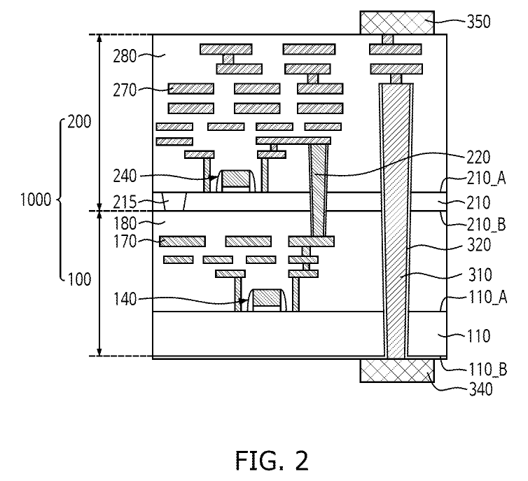

FIG. 2 is a cross-sectional view illustrating a semiconductor device according to some embodiments of the present disclosure.

Referring to FIG. 2, a semiconductor device according to some embodiments may include a logic die 1000, a through via 310, an upper pad 350, and a lower pad 340. The logic die 1000 may include a first semiconductor structure 100, a second semiconductor structure 200, and a first internal through via 220. The second semiconductor structure 200 may be stacked on the first semiconductor structure 100.

The first semiconductor structure 100 may include a first substrate 110, a first transistor 140, a first wiring structure 170, and a first interlayer insulating layer 180.

The first substrate 110 may be bulk silicon or silicon-on-insulator (SOI). Alternatively, the first substrate 110 may include single-element semiconductors such as silicon, germanium or various compound semiconductor materials such as silicon germanium (SiGe), silicon germanium-on-insulator (SGOI), indium antimonide (InSb), lead telluride (PbTe), indium arsenide (InAs), indium phosphide (InP), gallium arsenide (GaAs), gallium antimonide (GaSb), or silicon carbide (SiC). However, the present disclosure is not limited thereto.

The first substrate 110 may include a first surface 110_Aand a second surface 110_B opposite to the first surface 110_A. The first surface 110_A of the first substrate 110 may be a surface on which the first transistor 140 is disposed. The first surface 110_A of the first substrate 110 may be referred to as a front side of the first substrate 110. The second surface 110_B of the first substrate 110 may be referred to as a back side of the first substrate 110.

The first transistor 140 may be disposed on the first surface 110_A of the first substrate 110. The first transistor 140 may include a gate electrode, a gate insulating film, and a source/drain pattern. The first transistor 140 may include a planar MOSFET, a FinFET having a fin-shaped active region, a multi-bridge channel FET (MBCFET) or gate-all-around transistor including a plurality of channels vertically stacked on the active region, or a vertical FET (VFET), but the present disclosure is not limited thereto.

The first interlayer insulating layer 180 may be disposed on the first surface 110_A of the first substrate 110. The first interlayer insulating layer 180 may cover the first transistor 140. The first wiring structure 170 may be disposed in the first interlayer insulating layer 180. The first wiring structure 170 may be connected to the first transistor 140. For example, the first wiring structure 170 may be connected to the source/drain pattern and/or the gate electrode of the first transistor 140.

The first wiring structure 170 may include a plurality of wiring layers. A number of the wiring layers may vary according to design. In some embodiments, a thickness of each wiring layer of the first wiring structure 170 may differ. For example, a thickness of a wiring layer disposed adjacent to the first surface 110_A of the first substrate 110 may be smaller than a thickness of a wiring layer disposed farther from the first surface 110_A of the first substrate 110. However, the present disclosure is not limited thereto.

The second semiconductor structure 200 may include a second substrate 210, a second transistor 240, a second wiring structure 270, and a second interlayer insulating layer 280.

The second substrate 210 may be bulk silicon or SOI. Alternatively, the second substrate 210 may include single-element semiconductors such as silicon and germanium, or various compound semiconductor materials such as silicon germanium (SiGe), SGOI (silicon germanium-on-insulator), indium antimonide (InSb), lead telluride (PbTe), indium arsenide (InAs), indium phosphide (InP), gallium arsenide (GaAs), gallium antimonide (GaSb), or silicon carbide (SiC). However, the present disclosure is not limited thereto.

The second substrate 210 may include a third surface 210_A and a fourth surface 210_B opposite to the third surface 210_A. The third surface 210_A of the second substrate 210 may be a surface on which the second transistor 240 is disposed. The fourth surface 210_B of the second substrate 210 may face the first surface 110_A of the first substrate 110. The third surface 210_A of the second substrate 210 may be referred to as a front side of the second substrate 210. The fourth surface 210_B of the second substrate 210 may be referred to as a back side of the second substrate 210.

The second substrate 210 may be disposed on the first interlayer insulating layer 180. The second substrate 210 may contact the first interlayer insulating layer 180. For example, the fourth surface 210_B of the second substrate 210 may contact an upper surface of the first interlayer insulating layer 180.

In some embodiments, the logic die 1000 of the semiconductor device may further include a device isolation film 215. The device isolation film 215 may be disposed on an upper surface of the first interlayer insulating layer 180. The second substrate 210 may surround the device isolation film 215. In some embodiments, a lower surface of the device isolation film 215 may be disposed in the same plane as a lower surface of the second substrate 210. In other words, a distance from the third surface 210_A to the fourth surface 210_B of the second substrate 210 may be equal to a distance from the third surface 210_A of the second substrate 210 to the lower surface of the device isolation film 215. Here, “equal” may mean equal within a range including process tolerance.

The second transistor 240 may be disposed on the third surface 210_A of the second substrate 210. The second transistor 240 may include a gate electrode, a gate insulating film, and a source/drain pattern. The second transistor 240 may include a planar MOSFET, a FinFET having an active area with a fin structure, an MBCFET including a plurality of channels vertically stacked on the active area, a gate-all-around transistor, or a VFET, but the present disclosure is not limited thereto.

The second interlayer insulating layer 280 may be disposed on the third surface 210_A of the second substrate 210. The second interlayer insulating layer 280 may cover the second transistor 240. The second wiring structure 270 may be disposed in the second interlayer insulating layer 280. The second wiring structure 270 may be connected to the second transistor 240. For example, the second wiring structure 270 may be connected to the source/drain pattern and/or the gate electrode of the second transistor 240.

The second wiring structure 270 may include a plurality of wiring layers. The number of the wiring layers may vary according to design. In some embodiments, a thickness of each wiring layer of the second wiring structure 270 may differ. For example, a thickness of a wiring layer disposed adjacent to the third surface 210_A of the second substrate 210 may be smaller than a thickness of a wiring layer disposed farther from the third surface 210_A of the second substrate 210. However, the present disclosure is not limited thereto.

A plurality of first transistors 140 may be provided, and the plurality of first transistors 140 may constitute a first integrated circuit. The first integrated circuit may be, for example, a neural processing unit (NPU), a microprocessor, a central processing unit (CPU), a graphics processing unit (GPU), a digital signal processor (DSP), a cryptographic processor, an application processor (AP), a field-programmable gate array (FPGA), an application-specific integrated circuit (ASIC), or a memory controller, but the present disclosure is not limited thereto.

The first integrated circuit may perform arithmetic operations, logical operations, vector and matrix operations, and conditional operations and may process computations directly at a position adjacent to the plurality of memory dies (for example, the memory dies 2000 of FIG. 1) to reduce bandwidth consumption. The first integrated circuit may further include control functions such as instruction decoding, memory access control, and scheduling, and may include error handling functions. However, the present disclosure is not limited thereto.

In some embodiments, the first integrated circuit may perform data compression and decompression functions. The first integrated circuit may analyze data in the plurality of memory dies (for example, the memory dies 2000 of FIG. 1) to detect redundant or repeating patterns and may store those patterns in a compressed form according to a compression algorithm or restore them when necessary. Such functions may improve storage-space efficiency and reduce transfer volume between internal and external memory, thereby contributing to bandwidth and power consumption reduction. Compression schemes may be implemented in various forms, such as run-length encoding, dictionary-based compression, and lossless or lossy compression algorithms. The first integrated circuit may execute these algorithms through hardware logic or a microcontroller and may verify integrity of compressed data through hash operations or checksum calculation. In some embodiments, the first integrated circuit may perform a lightweight pattern-analysis function that automatically determines whether compression is to be applied according to data type. However, the present disclosure is not limited thereto.

In some embodiments, the first integrated circuit may perform AI-based inference functions such as neural-network computation, vector computation, and similarity determination by using algorithms such as lightweight neural networks, decision trees, and logistic regression. In some embodiments, the first integrated circuit may store and use weights, biases, activation functions, and the like required for AI operations such as data classification, feature extraction, and similarity search in the plurality of memory dies (the memory dies 2000 of FIG. 1) and may use optimized operation structures including integer-based operations, quantization, and pruning techniques. Such lightweight AI processing functions may realize both high-speed processing and low-power operation by directly performing data analysis and preprocessing at a position adjacent to the plurality of memory dies 2000.

A plurality of second transistors 240 may be provided, and the plurality of second transistors 240 may constitute a second integrated circuit. The second integrated circuit may perform a function of relaying data, addresses, and control signals received from a host die (for example, the host die 1200 of FIG. 11). The second integrated circuit may reorder or route signals received from the plurality of memory dies (for example, the memory dies 2000 of FIG. 1) to specific channels and may also perform a retiming function for delay compensation. In some embodiments, the second integrated circuit may perform conversion between an external interface and an internal interface, power distribution, and error-correcting-code (ECC)-based data-integrity assurance functions. Additionally, the second integrated circuit may interpret commands received from the host die and perform dispatch control based on the interpreted commands, or may perform clock synchronization and temperature and status monitoring functions. However, the present disclosure is not limited thereto.

Although the plurality of first transistors 140 have been described as constituting the first integrated circuit and the plurality of second transistors 240 have been described as constituting the second integrated circuit, the present disclosure is not limited thereto. For example, some of the plurality of first transistors 140 may constitute the first integrated circuit, and others of the plurality of first transistors 140 may constitute the second integrated circuit. Accordingly, the first semiconductor structure 100 may include the first integrated circuit and the second integrated circuit. Likewise, some of the plurality of second transistors 240 may constitute the second integrated circuit, and the remaining ones of the plurality of second transistors 240 may constitute the first integrated circuit. Accordingly, the second semiconductor structure 200 may include the first integrated circuit and the second integrated circuit.

The first internal through via 220 may extend in a direction perpendicular to the first surface 110_A of the first substrate 110. The first internal through via 220 may penetrate the second substrate 210. For example, the first internal through via 220 may penetrate the third surface 210_A and the fourth surface 210_B of the second substrate 210.

In some embodiments, the first internal through via 220 may electrically connect the first transistor 140 and the second transistor 240. One end of the first internal through via 220 may be electrically connected to the second wiring structure 270 and the second transistor 240. The other end of the first internal through via 220 may be electrically connected to the first wiring structure 170 and the first transistor 140. Accordingly, the first transistor 140 may transmit and receive signals to and from the second transistor 240 through the first internal through via 220.

The through via 310 may extend in a direction perpendicular to the first surface 110_A of the first substrate 110. The through via 310 may penetrate the first substrate 110, the first interlayer insulating layer 180, and the second substrate 210. One end of the through via 310 may be disposed in the second interlayer insulating layer 280. The second wiring structure 270 may be disposed on the through via 310. The second wiring structure 270 may be disposed between the through via 310 and the upper pad 350. The upper pad 350 may be disposed on an upper surface of the logic die 1000. The lower pad 340 may be disposed below a lower surface of the logic die 1000. The through via 310 may correspond to the through via 400 of FIG. 1, and each of the upper pad 350 and the lower pad 340 may correspond to the pad 450 of FIG. 1.

In some embodiments, a width of the through via 310 may not be uniform. For example, the width of the through via 310 may decrease as the through via 310 approaches the second surface 110_B of the first substrate 110. In terms of cross-sectional area, the through via 310 may have a tapered shape.

The through via 310 may be electrically connected to the second transistor 240 through the second wiring structure 270. Although the through via 310 is illustrated as being directly connected to the lower pad 340, the present disclosure is not limited thereto. For example, a wiring structure may be disposed between the through via 310 and the lower pad 340, and the through via 310 may be electrically connected to the lower pad 340 through the wiring structure. The lower pad 340 may receive a signal from an external structure (for example, an interposer). A signal may be supplied to the second transistor 240 through the lower pad 340, the through via 310, and the second wiring structure 270. The signal supplied to the second transistor 240 may be delivered to the upper pad 350 through the second wiring structure 270 or may be supplied to the first transistor 140 through the first internal through via 220 and the first wiring structure 170.

Although only one of each of the through via 310, the upper pad 350, and the lower pad 340 is illustrated, the present disclosure is not limited thereto. For example, the through via 310, the upper pad 350, and the lower pad 340 may each be provided as a plurality.

Each of the through via 310, the upper pad 350, and the lower pad 340 may include a conductive material. Each of the through via 310, the upper pad 350, and the lower pad 340 may include, for example, aluminum (Al), gold (Au), cobalt (Co), copper (Cu), nickel (Ni), lead (Pb), tantalum (Ta), tellurium (Te), titanium (Ti), tungsten (W), or a combination thereof.

A liner layer 320 may be disposed on a sidewall of the through via 310. The liner layer 320 may surround the through via 310. The liner layer 320 may be disposed between the through via 310 and the first substrate 110 and between the through via 310 and the second substrate 210. In some embodiments, the liner layer 320 may be disposed below the second surface 110_B of the first substrate 110. However, the present disclosure is not limited thereto. The liner layer 320 may include an insulating material.

Each of the first interlayer insulating layer 180 and the second interlayer insulating layer 280 may include at least one of silicon oxide, silicon nitride, silicon oxynitride, and low-k materials. The low-k material may include, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxyditertiary-butoxysiloxane (DADBS), trimethylsilyl phosphate (TMSP), polytetrafluoroethylene (PTFE), polyimide nanofoams such as polypropylene oxide, carbon-doped silicon oxide (CDO), organosilicate glass (OSG), SiLK, amorphous fluorinated carbon, silica aerogels, silica xerogels, mesoporous silica, or a combination thereof. However, the present disclosure is not limited thereto.

As functions implemented by increased integration density of semiconductor devices increase, complexity of transmitted and received signals correspondingly increases. For example, as the number of interconnect paths between adjacent dies increases, signal transmission and reception efficiency may decrease. A semiconductor device according to some embodiments may form the first transistor 140 and the second transistor 240 in a single die and arrange the first internal through via 220 connecting the first transistor 140 and the second transistor 240, thereby shortening a signal path from the first transistor 140 to the second transistor 240. As a result, signal transmission and reception efficiency from the first transistor 140 to the second transistor 240 may be improved and electrical characteristics of the semiconductor device may be enhanced.

In some embodiments, by forming the first transistor 140 disposed on the first substrate 110 and the second transistor 240 disposed on the second substrate 210 in a single die, thickness of the semiconductor device may be reduced. Accordingly, integration density of the semiconductor device may be improved. Here, the thickness may be a thickness in a direction perpendicular to the first surface 110_A of the first substrate 110.

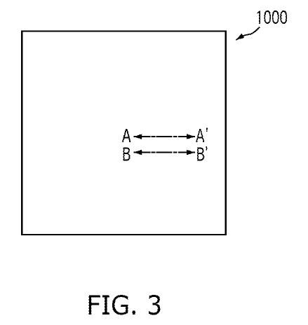

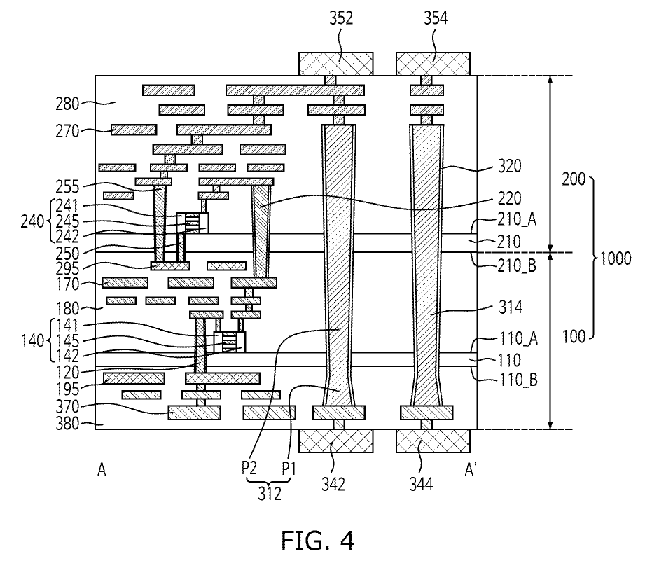

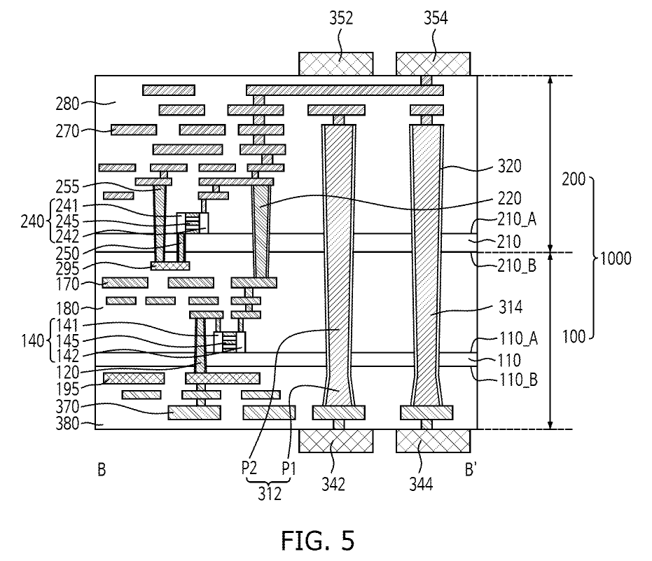

FIGS. 3-5 illustrate semiconductor devices according to some embodiments of the present disclosure. For reference, FIG. 3 is a plan view for explaining the logic die 1000 according to some embodiments, and FIGS. 4 and 5 are cross-sectional views taken along line A–A′ and line B–B′ of FIG. 3, respectively. For convenience of explanation, configurations other than those described with reference to FIG. 2 will be mainly described.

Referring to FIGS. 3-5, a semiconductor device according to some embodiments may include the logic die 1000, a first through via 312, a second through via 314, a first upper pad 352, a second upper pad 354, a first lower pad 342, and a second lower pad 344.

The logic die 1000 may include the first semiconductor structure 100 and the second semiconductor structure 200.

The first semiconductor structure 100 may include the first substrate 110, the first transistor 140, the first wiring structure 170, the first interlayer insulating layer 180, a second internal through via 120, a first power line 195, a third wiring structure 370, and a third interlayer insulating layer 380.

The first transistor 140 may be disposed on the first surface 110_A of the first substrate 110. The first transistor 140 may include a first source/drain pattern 141, a second source/drain pattern 142, a first gate electrode 145, and a first channel pattern.

The first wiring structure 170 may be disposed on the first transistor 140. The first wiring structure 170 may be connected to each of the first source/drain pattern 141 and the second source/drain pattern 142. For example, the first wiring structure 170 may electrically connect the first source/drain pattern 141 and the second internal through via 120. The first wiring structure 170 may electrically connect the second source/drain pattern 142 and the first internal through via 220. The first wiring structure 170 may be connected to the first gate electrode 145.

The second internal through via 120 may be disposed spaced apart from the first source/drain pattern 141. The second internal through via 120 may extend in a direction perpendicular to the first surface 110_A of the first substrate 110. The second internal through via 120 may be connected to the first wiring structure 170 and the first power line 195. In some embodiments, a width of the second internal through via 120 may not be uniform. For example, the width of the second internal through via 120 may increase as the second internal through via 120 extends away from the second substrate 210. Here, the width may be a width in a direction parallel to the first surface 110_A of the first substrate 110.

The first power line 195 may be disposed below the second surface 110_B of the first substrate 110. The first power line 195 may be disposed in the third interlayer insulating layer 380. The first power line 195 may extend in a direction parallel to the second surface 110_B of the first substrate 110. In some embodiments, power (for example, VDD, VSS, or GND) may be supplied to the first transistor 140 through the first power line 195. By disposing signal routing on the first surface 110_A of the first substrate 110 and disposing power routing on the second surface 110_B of the first substrate 110, routing of the semiconductor device may be efficiently designed. Accordingly, electrical characteristics and integration density of the semiconductor device may be improved.

In some embodiments, the second internal through via 120 may be omitted. In this case, for example, a source/drain contact may be formed under the first source/drain pattern 141. The source/drain contact may penetrate the first substrate 110 and may directly connect the first source/drain pattern 141 and the first power line 195.

The third interlayer insulating layer 380 may be disposed below the second surface 110_B of the first substrate 110. The first power line 195 and the third wiring structure 370 may be disposed in the third interlayer insulating layer 380. A lower surface of the third interlayer insulating layer 380 may be a lower surface of the logic die 1000. The third wiring structure 370 may be connected to the first power line 195. A description of a material of the third interlayer insulating layer 380 may be the same as the description of a material of the first interlayer insulating layer 180.

The second semiconductor structure 200 may include the second substrate 210, the second transistor 240, the second wiring structure 270, and the second interlayer insulating layer 280.

The second transistor 240 may be disposed on the third surface 210_A of the second substrate 210. The second transistor 240 may include a third source/drain pattern 241, a fourth source/drain pattern 242, a second gate electrode 245, and a second channel pattern.

The second wiring structure 270 may be disposed on the second transistor 240. The second wiring structure 270 may be connected to each of the fourth source/drain pattern 242 and a third internal through via 255. For example, as shown in FIG. 4, the second wiring structure 270 may electrically connect the third internal through via 255 and the first through via 312. As shown in FIG. 5, the second wiring structure 270 may electrically connect the fourth source/drain pattern 242 and the second through via 314. The second wiring structure 270 may be connected to the second gate electrode 245.

The third internal through via 255 may be disposed spaced apart from the third source/drain pattern 241. The third internal through via 255 may extend in a direction perpendicular to the first surface 110_A of the first substrate 110. The third internal through via 255 may be connected to the second wiring structure 270 and a second power line 295. In some embodiments, a width of the third internal through via 255 may not be uniform. For example, the width of the third internal through via 255 may increase as the third internal through via 255 extends away from the first substrate 110. Here, the width may be a width in a direction parallel to the first surface 110_A of the first substrate 110.

The second power line 295 may be disposed below the fourth surface 210_B of the second substrate 210. The second power line 295 may be disposed in the first interlayer insulating layer 180. The second power line 295 may extend in a direction parallel to the fourth surface 210_B of the second substrate 210. In some embodiments, power (for example, VDD, VSS, or GND) may be supplied to the second transistor 240 through the second power line 295. By disposing signal routing on the first surface 110_A of the first substrate 110 and disposing power routing below the second surface 110_B of the first substrate 110, routing of the semiconductor device may be efficiently designed.

A lower source/drain contact 250 may be disposed under the third source/drain pattern 241. The lower source/drain contact 250 may penetrate the second substrate 210. The lower source/drain contact 250 may electrically connect the third source/drain pattern 241 and the second power line 295.

The first through via 312 and the second through via 314 may extend in directions perpendicular to the first surface 110_A of the first substrate 110. The first through via 312 and the second through via 314 may penetrate the first substrate 110 and the second substrate 210. Since descriptions of shapes of the first through via 312 and the second through via 314 are the same, the description will focus on the first through via 312.

The first through via 312 may include a first portion P1 and a second portion P2. The first portion P1 of the first through via 312 may be disposed in the third interlayer insulating layer 380. The second portion P2 of the first through via 312 may penetrate the first substrate 110 and the second substrate 210. The first portion P1 and the second portion P2 of the first through via 312 may be distinguished by inclination. In terms of cross-sectional area, an inclination of a sidewall of the first portion P1 of the first through via 312 may differ from an inclination of a sidewall of the second portion P2 of the first through via 312. A width of the first portion P1 of the first through via 312 may increase as the first through via 312 extends toward the lower surface of the logic die 1000. A width of the second portion P2 of the first through via 312 may decrease as the first through via 312 extends toward the lower surface of the logic die 1000. Here, the width may be a width in a direction parallel to the first surface 110_A of the first substrate 110.

The first through via 312 may be electrically connected to each of the first upper pad 352 and the first lower pad 342. For example, the first through via 312 may be electrically connected to the first upper pad 352 through the second wiring structure 270. The first through via 312 may be electrically connected to the first lower pad 342 through the third wiring structure 370. In some embodiments, the first through via 312 may be electrically connected to the second power line 295 through the second wiring structure 270 and the third internal through via 255. A signal may be supplied to the second transistor 240 through the first through via 312, the second wiring structure 270, the third internal through via 255, and the second power line 295. A signal may be supplied to the outside through the first through via 312, the second wiring structure 270, and the first upper pad 352.

The second through via 314 may be electrically connected to the second lower pad 344. For example, the second through via 314 may be electrically connected to the second lower pad 344 through the third wiring structure 370. In some embodiments, the second through via 314 may be electrically connected to the fourth source/drain pattern 242 through the second wiring structure 270. A signal may be supplied to the second transistor 240 through the second through via 314 and the second wiring structure 270. A signal supplied to the second transistor 240 may be delivered to the second upper pad 354 through the second wiring structure 270 or may be supplied to the first transistor 140 through the first internal through via 220 and the first wiring structure 170.

The first upper pad 352 and the second upper pad 354 may be disposed on an upper surface of the logic die 1000. The first lower pad 342 and the second lower pad 344 may be disposed on a lower surface of the logic die 1000. Although the numbers of the upper pads 352 and 354 and the lower pads 342 and 344 are illustrated as two each, the present disclosure is not limited thereto.

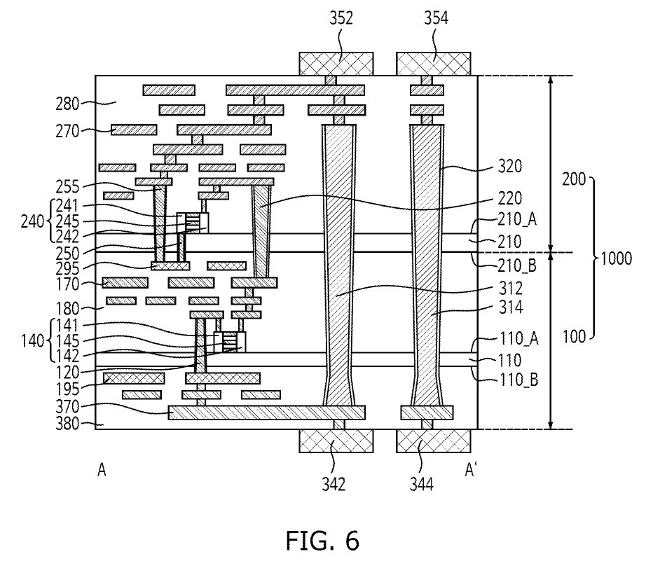

FIG. 6 is a cross-sectional view illustrating a semiconductor device according to some embodiments of the present disclosure. For convenience of explanation, configurations other than those described with reference to FIGS. 2-5 will be mainly described. For reference, FIG. 6 may correspond to a cross-sectional view taken along line A–A′ of FIG. 3.

Referring to FIG. 6, in a semiconductor device according to some embodiments, the third wiring structure 370 may be connected to the first through via 312. One end of the first through via 312 may be electrically connected to the first power line 195 through the third wiring structure 370. The other end of the first through via 312 may be electrically connected to the second power line 295 through the second wiring structure 270 and the third internal through via 255. For example, the first through via 312 may be electrically connected to each of the first power line 195 and the second power line 295. Accordingly, the same power signal may be supplied to each of the first transistor 140 and the second transistor 240.

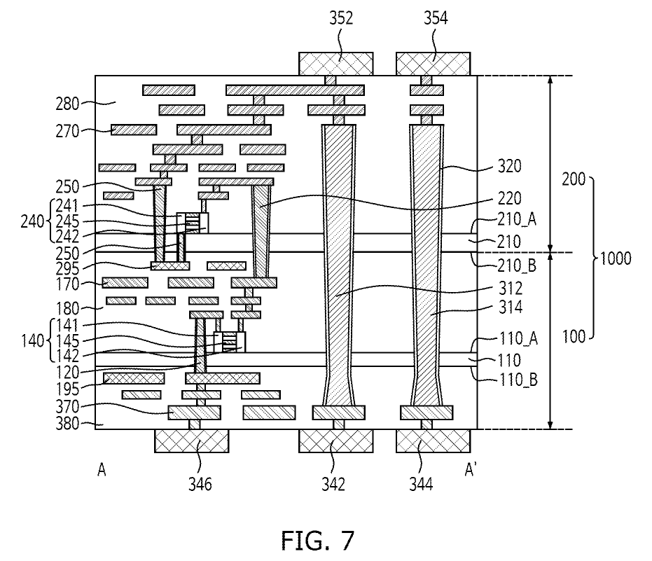

FIG. 7 is a cross-sectional view illustrating a semiconductor device according to some embodiments of the present disclosure. For convenience of explanation, configurations other than those described with reference to FIGS. 2-5 will be mainly described. For reference, FIG. 7 may correspond to a cross-sectional view taken along line A–A′ of FIG. 3.

Referring to FIG. 7, a semiconductor device according to some embodiments may further include a third lower pad 346.

The third lower pad 346 may be disposed below a lower surface of the logic die 1000. For example, the third lower pad 346 may be disposed below a lower surface of the third interlayer insulating layer 380. The third lower pad 346 may be spaced apart from the first lower pad 342. The third wiring structure 370 may be connected to the third lower pad 346. The third lower pad 346 may be electrically connected to the first power line 195 through the third wiring structure 370.

In some embodiments, the third lower pad 346 may be directly electrically connected to the first power line 195 through the third wiring structure 370. Here, “directly electrically connected” may mean electrically connected without passing through a separate component. For example, the first power line 195 may be electrically connected to the third lower pad 346 through the third wiring structure 370 without passing through the first through via 312. Accordingly, a power-signal path supplied through the first power line 195 may be shortened.

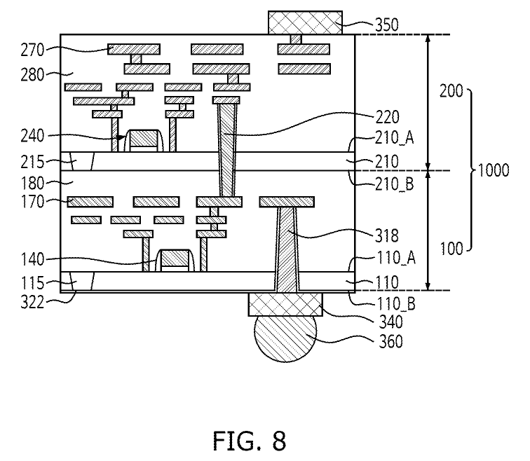

FIG. 8 is a view illustrating a semiconductor device according to some embodiments of the present disclosure. For convenience of explanation, configurations other than those described with reference to FIG. 2 will be mainly described.

Referring to FIG. 8, a semiconductor device according to some embodiments may include a logic die 1000, an upper pad 350, a lower pad 340, and a bump 360. The logic die 1000 may include the first semiconductor structure 100 and the second semiconductor structure 200.

The first semiconductor structure 100 may include a first substrate 110, a first transistor 140, a first wiring structure 170, a first interlayer insulating layer 180, and a lower through via 318.

The lower through via 318 may penetrate a portion of the first interlayer insulating layer 180 and the first substrate 110. One end of the lower through via 318 may be disposed in the first interlayer insulating layer 180 and may be disposed on the first wiring structure 170. The lower through via 318 may be electrically connected to the first wiring structure 170. The other end of the lower through via 318 may penetrate the first substrate 110. The lower pad 340 may be disposed on the other end of the lower through via 318. The lower through via 318 may be electrically connected to the lower pad 340. A liner layer 322 may be disposed on a sidewall of the lower through via 318 and on the second surface 110_B of the first substrate 110.

In some embodiments, the logic die 1000 of the semiconductor device may further include a lower device isolation film 115. The lower device isolation film 115 may be disposed in the first substrate 110. The first substrate 110 may surround a sidewall of the lower device isolation film 115. In some embodiments, an upper surface of the lower device isolation film 115 may be disposed in the same plane as the first surface 110_A of the first substrate 110. A lower surface of the lower device isolation film 115 may be disposed in the same plane as the second surface 110_B of the first substrate 110. However, the present disclosure is not limited thereto.

The bump 360 may be disposed below the lower pad 340. The bump 360 may be electrically connected to the lower pad 340. The bump 360 may deliver a signal supplied from the outside to the lower pad 340. The bump 360 may be a solder bump including a low-melting-point metal, for example, tin (Sn) or a tin alloy, but the present disclosure is not limited thereto. The bump 360 may have various shapes such as a land, a ball, a pin, or a pillar. The bump 360 may be formed in a single layer or multiple layers. When the bump 360 is formed in a single layer, the bump 360 may include Sn–Ag solder or copper (Cu). However, the present disclosure is not limited thereto.

The second semiconductor structure 200 may include a second substrate 210, a second transistor 240, a second wiring structure 270, and a second interlayer insulating layer 280.

The second wiring structure 270 may be electrically connected to the upper pad 350. The upper pad 350 may be electrically connected to the second transistor 240 through the second wiring structure 270. In some embodiments, a signal may be supplied to the second transistor 240 through the upper pad 350 and the second wiring structure 270. Alternatively, a signal may be delivered from the second transistor 240 to the upper pad 350 through the second wiring structure 270.

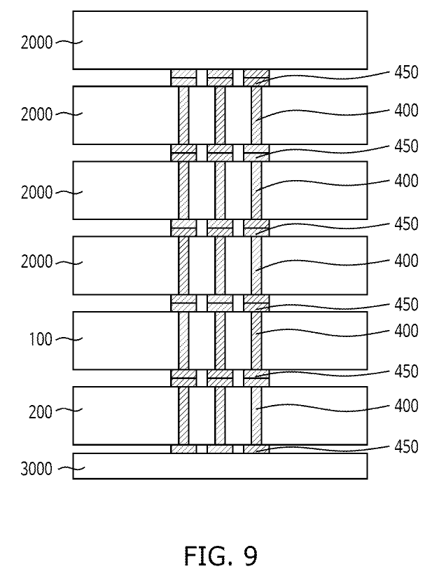

FIG. 9 is a view illustrating a semiconductor device according to some embodiments of the present disclosure. For convenience of explanation, configurations other than those described with reference to FIGS. 1 and 2 will be mainly described.

Referring to FIG. 9, a semiconductor device according to some embodiments may include a first semiconductor structure 100, a second semiconductor structure 200, a plurality of memory dies 2000, an interposer 3000, a plurality of through vias 400, and a plurality of pads 450.

The second semiconductor structure 200 may be stacked on the interposer 3000. The second semiconductor structure 200 may include the second integrated circuit. A description of the second integrated circuit may be the same as that provided with reference to FIG. 2. In some embodiments, the second semiconductor structure 200 may be referred to as a buffer die.

The first semiconductor structure 100 may be stacked on the second semiconductor structure 200. The first semiconductor structure 100 may be spaced apart from the second semiconductor structure 200. The plurality of pads 450 may be disposed between the first semiconductor structure 100 and the second semiconductor structure 200. The first semiconductor structure 100 may include the first integrated circuit. A description of the first integrated circuit may be the same as that provided with reference to FIG. 2. In some embodiments, the first semiconductor structure 100 may be referred to as a processor die.

The plurality of memory dies 2000 may be stacked on the first semiconductor structure 100. The first semiconductor structure 100, the second semiconductor structure 200, and each of the memory dies 2000 may be electrically connected through the plurality of through vias 400 and the plurality of pads 450. By disposing the plurality of memory dies 2000 on the first semiconductor structure 100, a signal path between the first semiconductor structure 100 and the plurality of memory dies 2000 may be shortened.

Although the first semiconductor structure 100 is illustrated as being disposed under the plurality of memory dies 2000, the present disclosure is not limited thereto. For example, the first semiconductor structure 100 may be disposed between two of the plurality of memory dies 2000. In some embodiments, the number of the first semiconductor structures 100 may be plural.

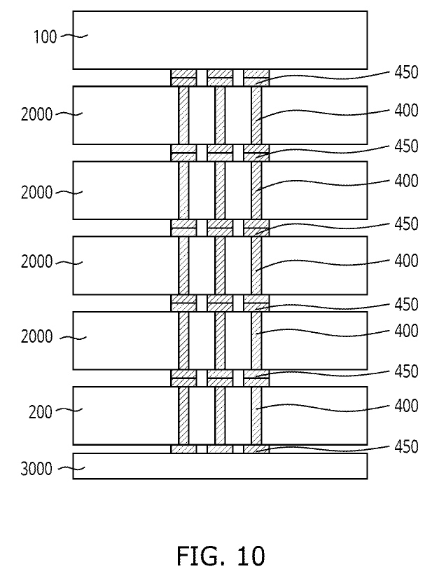

FIG. 10 is a view illustrating a semiconductor device according to some embodiments of the present disclosure. For convenience of explanation, configurations other than those described with reference to FIGS. 1 and 2 will be mainly described.

Referring to FIG. 10, a semiconductor device according to some embodiments may include a first semiconductor structure 100, a second semiconductor structure 200, a plurality of memory dies 2000, an interposer 3000, a plurality of through vias 400, and a plurality of pads 450.

The second semiconductor structure 200 may be stacked on the interposer 3000. The second semiconductor structure 200 may include the second integrated circuit. A description of the second integrated circuit may be the same as that provided with reference to FIG. 2. In some embodiments, the second semiconductor structure 200 may be referred to as a buffer die.

The plurality of memory dies 2000 may be stacked on the second semiconductor structure 200. The first semiconductor structure 100 may be stacked on the plurality of memory dies 2000. The first semiconductor structure 100 may be stacked on an uppermost one of the plurality of memory dies 2000. The first semiconductor structure 100 may include the first integrated circuit. A description of the first integrated circuit may be the same as that provided with reference to FIG. 2. In some embodiments, the first semiconductor structure 100 may be referred to as a processor die.

The first semiconductor structure 100, the second semiconductor structure 200, and each of the memory dies 2000 may be electrically connected through the plurality of through vias 400 and the plurality of pads 450. By disposing the first semiconductor structure 100 on the plurality of memory dies 2000, a signal path between the first semiconductor structure 100 and the plurality of memory dies 2000 may be shortened.

In some embodiments, by disposing the first semiconductor structure 100 on the upper parts of the plurality of memory dies 2000, the plurality of through vias 400 may not be disposed in the first semiconductor structure 100. As a result, an area in which the plurality of through vias 400 are disposed is unnecessary in the first semiconductor structure 100, and the first integrated circuit may be additionally disposed in that area. In some embodiments, by disposing the first semiconductor structure 100 on the upper parts of the plurality of memory dies 2000, heat generated in the first semiconductor structure 100 may be easily dissipated to the outside.

FIG. 11 is a view illustrating a semiconductor package according to some embodiments of the present disclosure.

Referring to FIG. 11, the semiconductor package may include a stacked memory device 1100, a host die 1200, an interposer 1300, and a package substrate 1400. The stacked memory device 1100 may be any one of the memory devices described with reference to FIGS. 1-10 and may include the logic die 1000 and memory dies 1120-1150. Each of the memory dies 1120-1150 may include a memory-cell array. The logic die 1000 may be any one of the logic dies 1000 described with reference to FIGS. 1-8. The logic die 1000 may be electrically connected to a physical layer 1210 of the host die 1200 through the interposer 1300. The stacked memory device 1100 may receive signals from the host die 1200 through the second semiconductor structure 200 of the logic die 1000 or may transmit signals to the host die 1200.

The second semiconductor structure 200 of the logic die 1000 may provide an access path capable of transmitting and receiving signals with the stacked memory device 1100 without passing through the host die 1200. The second semiconductor structure 200 of the logic die 1000 may include a through via 1101 capable of directly communicating with an external device. Signals and data received at the second semiconductor structure 200 may be transmitted to the plurality of memory dies 1120-1150 through the through vias 1101. Data read from the plurality of memory dies 1120-1150 may be transmitted to an external device through the through vias 1101 and the second semiconductor structure 200.

The logic die 1000 and the plurality of memory dies 1120-1150 may be electrically connected through the through vias 1101 and bumps 1102. The logic die 1000 may receive signals provided to each channel through the bumps 1102 allocated per channel from the host die 1200. Although the through vias 1101 are illustrated as being directly connected to the bumps 1102, the present disclosure is not limited thereto. For example, a pad may be disposed between each bump 1102 and each through via 1101.

The host die 1200 may execute applications supported by the semiconductor package by using the stacked memory device 1100. For example, the host die 1200 may include at least one processor such as a CPU, an AP, a GPU, an NPU, a tensor processing unit (TPU), a vision processing unit (VPU), an image signal processor (ISP), or a DSP, and may execute specialized computations.

The host die 1200 may include a physical layer 1210 and a memory controller 1220. The physical layer 1210 may include I/O circuits for transmitting and receiving signals to and from the logic die 1000 of the stacked memory device 1100. The host die 1200 may provide various signals to the logic die 1000 through the physical layer 1210. The signals provided to the logic die 1000 may be delivered to the plurality of memory dies 1120-1150 through interface circuits of the logic die 1000 and the through vias 1101.

The memory controller 1220 may control overall operations of the stacked memory device 1100. The memory controller 1220 may transmit signals for controlling the stacked memory device 1100 to the stacked memory device 1100 through the physical layer 1210. Additionally or alternatively, the memory controller 1220 may be included in the logic die 1000. For example, part of the memory controller 1220 may be included in the first semiconductor structure 100 of the logic die 1000.

The interposer 1300 may connect the stacked memory device 1100 to the host die 1200. The interposer 1300 may connect the logic die 1000 of the stacked memory device 1100 to the physical layer 1210 of the host die 1200 and may provide physical paths formed using conductive materials. Accordingly, the stacked memory device 1100 and the host die 1200 may be stacked on the interposer 1300 and may transmit and receive signals to and from each other.

Bumps 1103 may be attached to an upper surface of the package substrate 1400, and solder balls 1104 may be attached to a lower surface of the package substrate 1400. For example, the bumps 1103 may be flip-chip bumps. The interposer 1300 may be stacked on the package substrate 1400 through the bumps 1103. The semiconductor package 1000 may transmit and receive signals to and from another external package or semiconductor device through the solder balls 1104. For example, the package substrate 1400 may be a printed-circuit board (PCB).

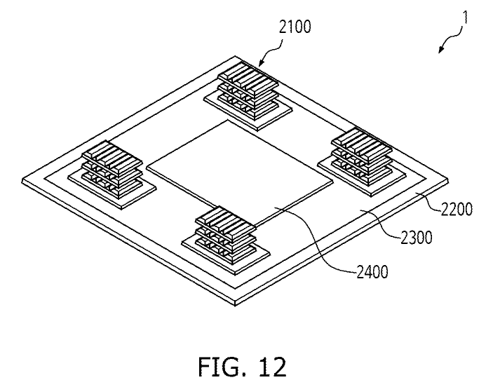

FIG. 12 is a view illustrating a semiconductor package according to some embodiments of the present disclosure.

Referring to FIG. 12, a semiconductor package 1 may include stacked memory devices 2100 and a host die 2400. The stacked memory devices 2100 and the host die 2400 may be stacked on an interposer 2300, and the interposer 2300 may be stacked on a package substrate 2200. The semiconductor package 1 may transmit and receive signals to and from another external package or semiconductor device through solder balls attached to a lower surface of the package substrate 2200.

Each stacked memory device 2100 may be implemented based on an HBM standard. However, the present disclosure is not limited thereto, and each stacked memory device 2100 may be implemented based on a GDDR, HMC, or wide-I/O standard. Each stacked memory device 2100 may correspond to the stacked memory device 1100 of FIG. 11.

The host die 2400 may be implemented as a system-on-chip (SoC) including at least one processor such as a CPU, an AP, a GPU, or an NPU. The host die 2400 may correspond to the host die 1200 of FIG. 11.

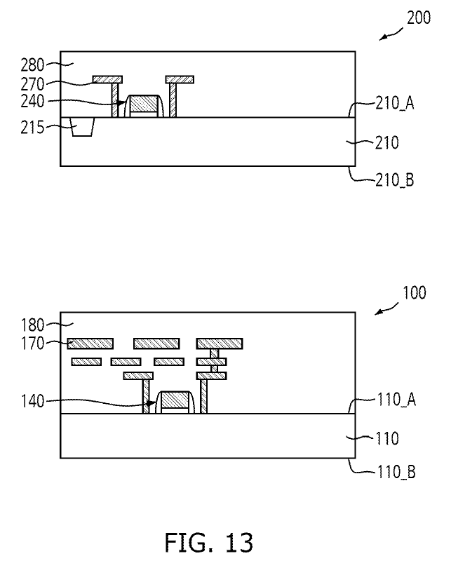

FIGS. 13-18 are views illustrating methods of manufacturing a semiconductor device according to some embodiments of the present disclosure. For convenience of explanation, configurations identical to those described with reference to FIG. 2 are omitted or briefly described.

Referring to FIG. 13, a method of manufacturing a semiconductor device according to some embodiments may form the first semiconductor structure 100 and the second semiconductor structure 200 on different wafers.

The first semiconductor structure 100 may be formed on a first wafer. For example, the first substrate 110 may be formed on the first wafer, and the first transistor 140, the first wiring structure 170, and the first interlayer insulating layer 180 may be formed on the first substrate 110.

The second semiconductor structure 200 may be formed on a second wafer. For example, the second substrate 210 may be formed on the second wafer, and the second transistor 240, the second wiring structure 270, and the second interlayer insulating layer 280 may be formed on the second substrate 210. In some embodiments, the device isolation film 215 may be formed in the second substrate 210.

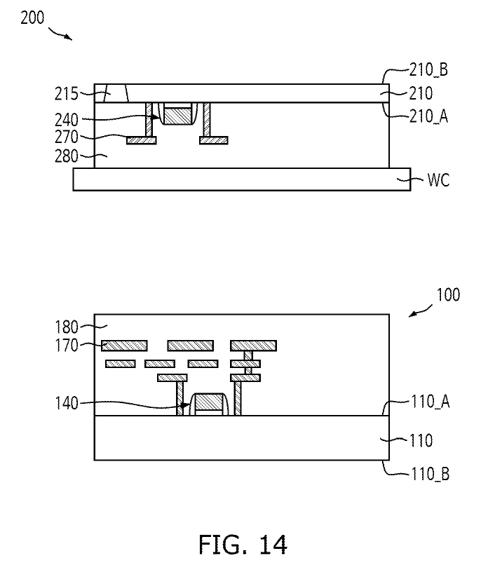

Referring to FIG. 14, the second semiconductor structure 200 may be rotated, and a portion of the second substrate 210 may be removed. Specifically, a wafer carrier WC may carry and rotate the second semiconductor structure 200. Specifically, the second semiconductor structure 200 may be rotated by the wafer carrier WC so that the fourth surface 210_B of the second substrate 210 is positioned at an uppermost portion. Then, a portion of the second substrate 210 may be removed so that a thickness of the second substrate 210 may be reduced. Here, the thickness may be a thickness in a direction perpendicular to the third surface 210_A of the second substrate 210.

In some embodiments, the thickness of the second substrate 210 may be reduced by a chemical-mechanical polishing (CMP) process on the second substrate 210. For example, the device isolation film 215 may function as a stopper in the CMP process. However, the present disclosure is not limited thereto. In the CMP process for reducing the thickness of the second substrate 210, a method using an SOI substrate or a doping gradation of a substrate may be performed.

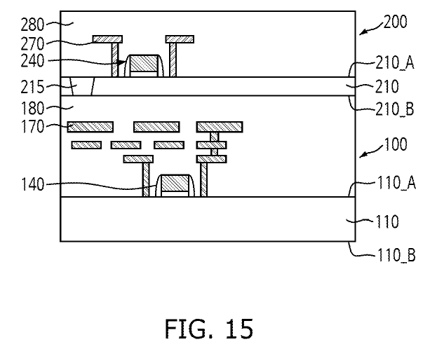

Referring to FIG. 15, the first semiconductor structure 100 and the second semiconductor structure 200 may be bonded.

Specifically, the fourth surface 210_B of the second substrate 210 may be disposed on the first interlayer insulating layer 180 of the first semiconductor structure 100. In some embodiments, a dielectric layer may be formed on the fourth surface 210_B of the second substrate 210 of the second semiconductor structure 200. Then, the dielectric layer and the first interlayer insulating layer 180 may be bonded by dielectric-to-dielectric bonding. However, the present disclosure is not limited thereto.

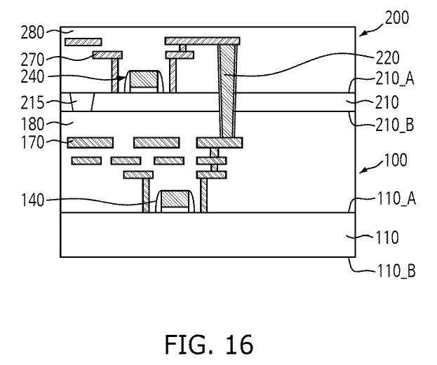

Referring to FIG. 16, the first internal through via 220 penetrating the second substrate 210 may be formed, and the second wiring structure 270 may be connected on the first internal through via 220. The first internal through via 220 may extend in a direction perpendicular to the third surface 210_A of the second substrate 210 and may be connected to the first wiring structure 170. The first transistor 140 may be electrically connected to the second transistor 240 through the first internal through via 220.

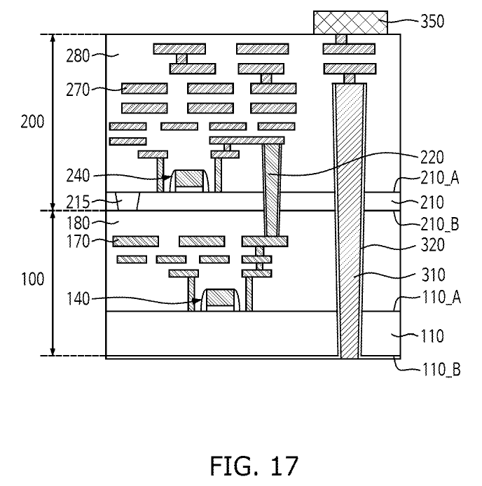

Referring to FIG. 17, the through via 310 may be formed, and the second wiring structure 270 may be connected to the through via 310. The through via 310 may extend in a direction perpendicular to the third surface 210_A of the second substrate 210 and may penetrate the second substrate 210, the first interlayer insulating layer 180, and the first substrate 110. Before the through via 310 is formed, the liner layer 320 may be formed, and the through via 310 may be formed in the liner layer 320. Then, a wiring layer of the second wiring structure 270 may be formed so as to be connected to the through via 310. Then, the upper pad 350 may be formed on an upper surface of the second interlayer insulating layer 280. The upper pad 350 may be electrically connected to the through via 310 through the second wiring structure 270.

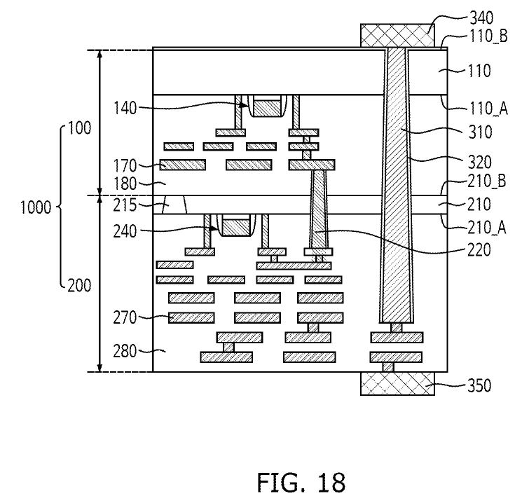

Referring to FIG. 18, the logic die 1000 may be rotated, and the lower pad 340 may be formed on the second surface 110_B of the first substrate 110. The lower pad 340 may be electrically connected to the through via 310. In some embodiments, a wiring structure may be formed between the lower pad 340 and the through via 310. The lower pad 340 and the through via 310 may be electrically connected through the wiring structure.

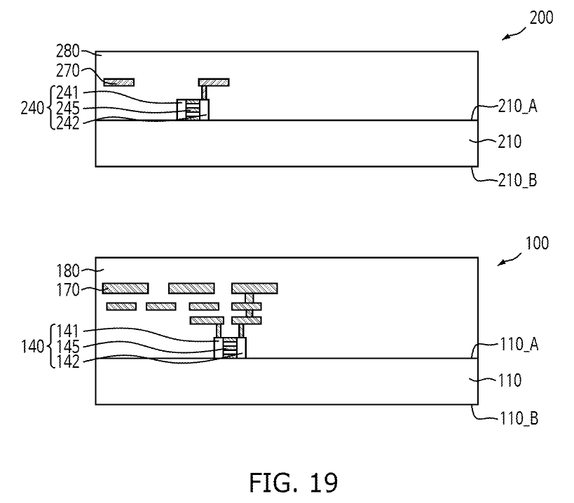

FIGS. 19-23 are views illustrating methods of manufacturing a semiconductor device according to some embodiments of the present disclosure. For reference, FIGS. 19-23 may correspond to cross-sectional views taken along line A–A′ of FIG. 3. For convenience of explanation, configurations identical to those described with reference to FIGS. 2-5 are omitted or briefly described.

Referring to FIG. 19, a method of manufacturing a semiconductor device according to some embodiments may form the first semiconductor structure 100 and the second semiconductor structure 200 on different wafers.

The first semiconductor structure 100 may be formed on a first wafer. For example, the first substrate 110 may be formed on the first wafer, and the first transistor 140, the first wiring structure 170, and the first interlayer insulating layer 180 may be formed on the first substrate 110. The first transistor 140 may include the first source/drain pattern 141, the second source/drain pattern 142, and the first gate electrode 145.

The second semiconductor structure 200 may be formed on a second wafer. For example, the second substrate 210 may be formed on the second wafer, and the second transistor 240, the second wiring structure 270, and the second interlayer insulating layer 280 may be formed on the second substrate 210. The second transistor 240 may include the third source/drain pattern 241, the fourth source/drain pattern 242, and the second gate electrode 245.

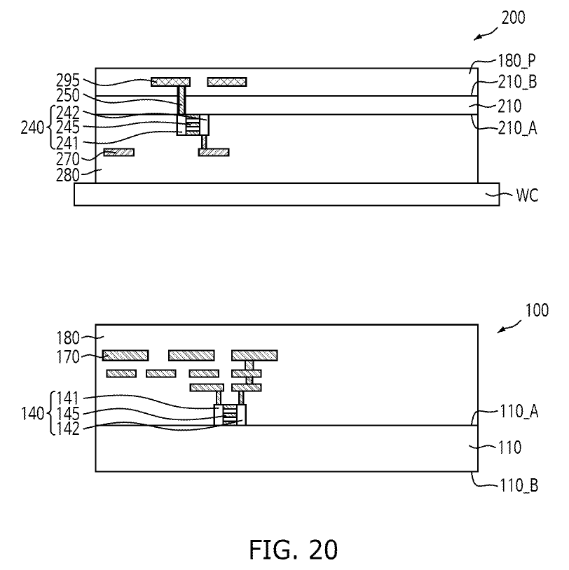

Referring to FIG. 20, the second semiconductor structure 200 may be rotated, a lower source/drain contact 250 may be formed on the third source/drain pattern 241, and the second power line 295 may be formed.

Specifically, the second semiconductor structure 200 may be rotated by the wafer carrier WC so that the fourth surface 210_B of the second substrate 210 is positioned at an uppermost portion. Then, the lower source/drain contact 250 penetrating the second substrate 210 and connected to the third source/drain pattern 241 may be formed. Then, a pre-first interlayer insulating layer 180_P and the second power line 295 may be formed. The second power line 295 may be formed in the pre-first interlayer insulating layer 180_P.

In some embodiments, before the lower source/drain contact 250 is formed, a portion of the second substrate 210 may be removed so that a thickness of the second substrate 210 may be reduced. For example, the thickness of the second substrate 210 may be reduced by a CMP process on the second substrate 210. The CMP process may use a device isolation film, an SOI substrate, or a doping gradation of a substrate.

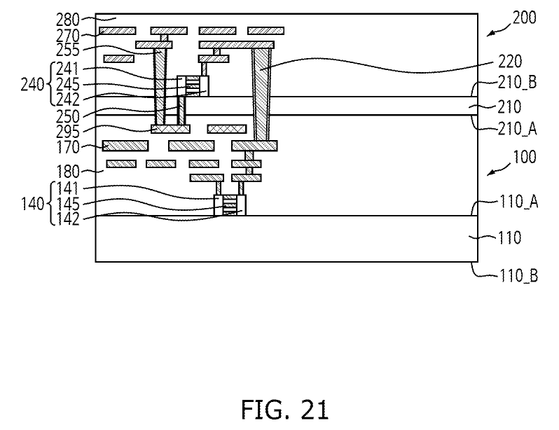

Referring to FIG. 21, the first semiconductor structure 100 and the second semiconductor structure 200 may be bonded.

Specifically, the pre-first interlayer insulating layer 180_P of the second semiconductor structure 200 may be disposed on the first interlayer insulating layer 180 of the first semiconductor structure 100. The first interlayer insulating layer 180 and the pre-first interlayer insulating layer 180_P may be bonded by dielectric-to-dielectric bonding.

Then, the first internal through via 220 and the third internal through via 255 may be formed. The first internal through via 220 may penetrate the second substrate 210 and may be connected to the first wiring structure 170. The third internal through via 255 may penetrate the second substrate 210 and may be connected to the second power line 295. Then, wiring layers of the second wiring structure 270 may be formed so as to be connected to the first internal through via 220 and the third internal through via 255, respectively.

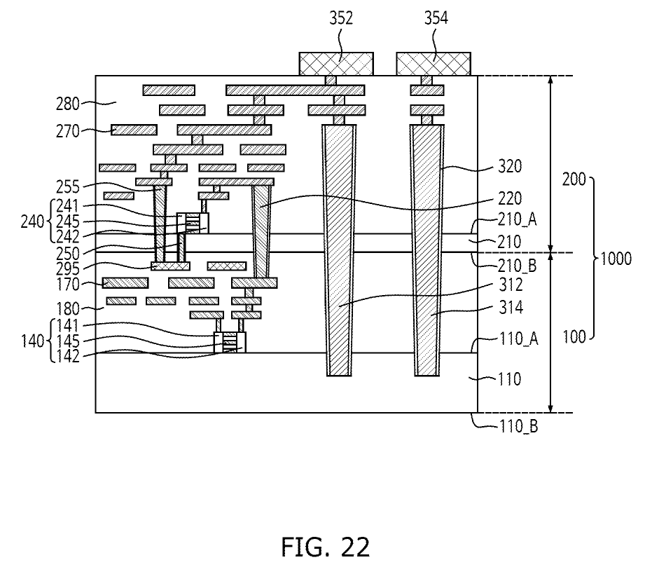

Referring to FIG. 22, the first through via 312 and the second through via 314 may be formed, and the second wiring structure 270 may be connected to the first through via 312 and the second through via 314. Each of the first through via 312 and the second through via 314 may penetrate the second substrate 210, the first interlayer insulating layer 180, and the first surface 110_A of the first substrate 110. One end of each of the first through via 312 and the second through via 314 may be disposed in the first substrate 110. Before the first through via 312 and the second through via 314 are formed, the liner layer 320 may be formed, and the first through via 312 and the second through via 314 may be formed in the liner layer 320.

Then, wiring layers of the second wiring structure 270 may be formed so as to be connected to the first through via 312 and the second through via 314. Then, the first upper pad 352 and the second upper pad 354 may be formed on an upper surface of the second interlayer insulating layer 280. The first upper pad 352 may be electrically connected to the first through via 312 through the second wiring structure 270, and the second upper pad 354 may be electrically connected to the second through via 314 through the second wiring structure 270.

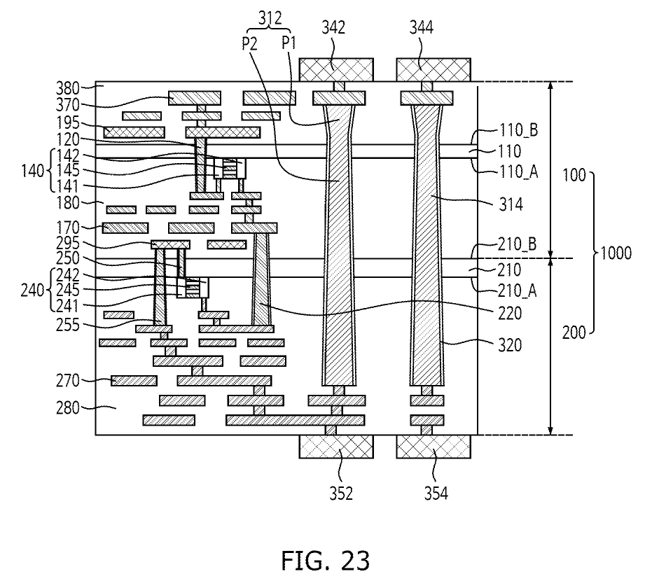

Referring to FIG. 23, the logic die 1000 may be rotated, and the second internal through via 120, the first power line 195, and the third wiring structure 370 may be formed.

Specifically, the logic die 1000 may be rotated so that the second surface 110_B of the first substrate 110 is positioned at an uppermost portion. Then, a portion of the first substrate 110 may be removed so that a thickness of the first substrate 110 may be reduced. Then, the second internal through via 120 penetrating the first substrate 110 and connected to the first wiring structure 170 may be formed. The second internal through via 120 may be electrically connected to the first source/drain pattern 141 through the first wiring structure 170.

Then, the first power line 195 may be formed on the second internal through via 120. The first power line 195 may be connected to the second internal through via 120. Then, the first portion P1 of the first through via 312 and the first portion of the second through via 314 may be formed. Accordingly, portions having different inclinations, that is, the first portion and the second portion, of each of the first through via 312 and the second through via 314 may be formed. Then, the third wiring structure 370 may be formed. The third wiring structure 370 may be connected to the first power line 195 and each of the first through via 312 and the second through via 314. Then, the first lower pad 342 and the second lower pad 344 may be formed on the third interlayer insulating layer 380.

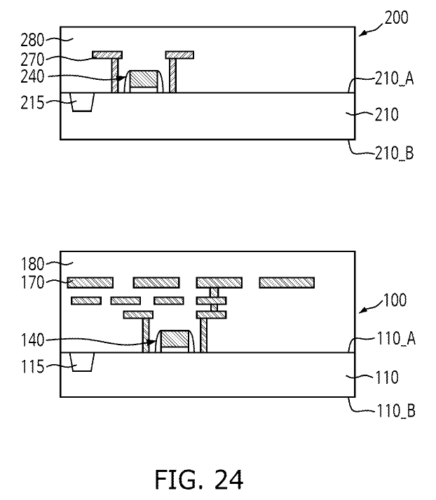

FIGS. 24-28 are views illustrating methods of manufacturing a semiconductor device according to some embodiments of the present disclosure. For convenience of explanation, configurations identical to those described with reference to FIGS. 8 and 13-18 are omitted or briefly described.

Referring to FIG. 24, a method of manufacturing a semiconductor device according to some embodiments may form the first semiconductor structure 100 and the second semiconductor structure 200 on different wafers.

The first semiconductor structure 100 may be formed on a first wafer. For example, the first substrate 110 may be formed on the first wafer, and the first transistor 140, the first wiring structure 170, and the first interlayer insulating layer 180 may be formed on the first substrate 110. In some embodiments, the lower device isolation film 115 may be formed in the first substrate 110.

The second semiconductor structure 200 may be formed on a second wafer. For example, the second substrate 210 may be formed on the second wafer, and the second transistor 240, the second wiring structure 270, and the second interlayer insulating layer 280 may be formed on the second substrate 210. In some embodiments, the device isolation film 215 may be formed in the second substrate 210.

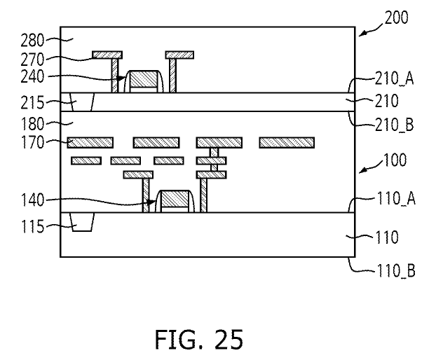

Referring to FIG. 25, a portion of the second substrate 210 may be removed, and the first semiconductor structure 100 and the second semiconductor structure 200 may be bonded. A method of removing the portion of the second substrate 210 may be the same as that described with reference to FIG. 15. A method of bonding the first semiconductor structure 100 and the second semiconductor structure 200 may be the same as that described with reference to FIG. 16.

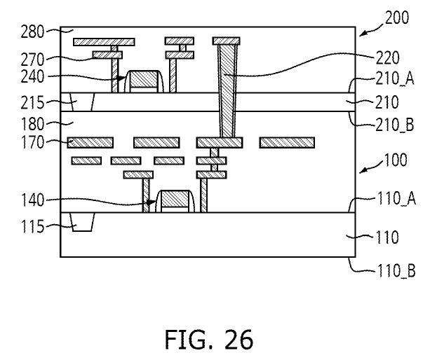

Referring to FIG. 26, the first internal through via 220 penetrating the second substrate 210 may be formed, and the second wiring structure 270 may be connected on the first internal through via 220. The first transistor 140 may be electrically connected to the second transistor 240 through the first internal through via 220.

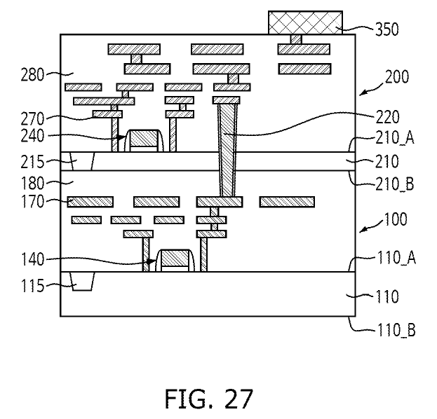

Referring to FIG. 27, the upper pad 350 may be formed on an upper surface of the second semiconductor structure 200. The upper pad 350 may be disposed on an upper surface of the second interlayer insulating layer 280. A wiring layer of the second wiring structure 270 may be formed so as to be connected to the upper pad 350. The upper pad 350 may be electrically connected to the second transistor 240 through the second wiring structure 270.

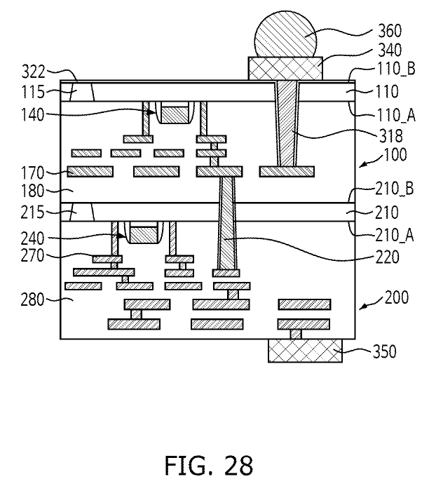

Referring to FIG. 28, a portion of the first substrate 110 may be removed, and the lower through via 318, the lower pad 340, and the bump 360 may be formed.

For example, the first semiconductor structure 100 and the second semiconductor structure 200 may be rotated so that the second surface 110_B of the first substrate 110 is positioned at an uppermost portion. Then, a portion of the first substrate 110 may be removed. In the process of removing the first substrate 110, the lower device isolation film 115 may function as a stopper.

Then, a trench may be formed in the first substrate 110 and the first interlayer insulating layer 180. A bottom surface of the trench may expose the first wiring structure 170. Then, the liner layer 322 may be formed on a sidewall of the trench and on the second surface 110_B of the first substrate 110. The liner layer 322 may include an insulating material. Then, the lower through via 318 may be formed in the trench. The lower through via 318 may be electrically connected to the first wiring structure 170. Then, the lower pad 340 and the bump 360 may be formed on the lower through via 318.

According to some embodiments of the present disclosure, a method of manufacturing a semiconductor device includes forming a first semiconductor structure including a first substrate and a first transistor, forming a second semiconductor structure including a second substrate and a second transistor, bonding the first semiconductor structure and the second semiconductor structure, forming an internal through via that electrically connects the first transistor and the second transistor, and forming a through via that penetrates the first substrate and the second substrate.

In some embodiments, the internal through via may penetrate the first substrate.

In some embodiments, bonding the first semiconductor structure and the second semiconductor structure may include removing a portion of the second substrate and bonding the second semiconductor structure on an interlayer insulating layer of the first semiconductor structure.

In some embodiments, the method of manufacturing a semiconductor device may further include forming a lower pad and an upper pad connected to the through via.

In some embodiments, forming the second semiconductor structure including the second substrate and the second transistor on a second wafer may include: forming the second transistor on the second substrate, forming a lower source/drain contact that penetrates the second substrate and is electrically connected to the second transistor, and forming a first power line on the lower source/drain contact.

In some embodiments, the method of manufacturing a semiconductor device may further include, before forming the through via, forming a first wiring structure that is electrically connected to the first power line and disposed on the second transistor.

In some embodiments, the method of manufacturing a semiconductor device may further include forming a second power line on a back surface of the first substrate.

In some embodiments, the method of manufacturing a semiconductor device may further include forming a second wiring structure connected to the second power line and a lower pad connected to the second wiring structure.

In some embodiments, the method of manufacturing a semiconductor device may further include exposing the through via by removing a portion of the first substrate and forming a portion of the through via in an interlayer insulating layer disposed on the back surface of the first substrate.

In some embodiments, the through via may include a first portion disposed in the interlayer insulating layer and a second portion penetrating the first substrate and the second substrate, and an inclination of a sidewall of the first portion may differ from an inclination of a sidewall of the second portion.

While the present disclosure contains many specific embodiment details, these should not be construed as limitations on the scope of any invention or on the scope of what may be claimed, but rather as descriptions of features that may be specific to particular embodiments of particular inventions. Certain features that are described in this specification in the context of separate embodiments can also be implemented in combination in a single implementation. Conversely, various features that are described in the context of a single embodiment can also be implemented in multiple embodiments separately or in any suitable subcombination. Moreover, although features may be described above as acting in certain combinations, one or more features from a combination can in some cases be excised from the combination, and the combination may be directed to a subcombination or variation of a subcombination.

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

What is claimed is:

1. A semiconductor device comprising:
a logic die;
a first through via extending into at least a portion of the logic die;
an upper pad on an upper surface of the logic die;
a lower pad below a lower surface of the logic die and electrically connected to the first through via; and
a plurality of memory dies stacked on the logic die,
wherein the logic die comprises:
a first substrate comprising a first surface and a second surface opposite to the first surface;
a first transistor on the first surface of the first substrate;
a second substrate comprising:
a third surface, and
a fourth surface opposite to the third surface and facing the first surface of the first substrate;
a second transistor on the third surface of the second substrate; and
an internal through via extending into the second substrate, wherein the first transistor and the second transistor are connected through the internal through via.

2. The semiconductor device of claim 1, wherein the first through via extends into the first substrate and the second substrate.

3. The semiconductor device of claim 1, wherein the logic die comprises a first interlayer insulating layer on the first surface of the first substrate, and
the fourth surface of the second substrate is in contact with the first interlayer insulating layer.

4. The semiconductor device of claim 3, wherein the first through via extends into the first interlayer insulating layer.

5. The semiconductor device of claim 3, wherein the logic die comprises a device isolation film on the first interlayer insulating layer, and
wherein the second substrate is outside a periphery of the device isolation film.

6. The semiconductor device of claim 1, wherein the logic die comprises a first wiring structure on the first transistor and a second wiring structure on the second transistor, and
wherein the internal through via is between the first wiring structure and the second wiring structure.

7. The semiconductor device of claim 1, comprising an interposer under the logic die and electrically connected to the lower pad.

8. The semiconductor device of claim 7, wherein the first transistor is electrically connected to a controller through the interposer.

9. The semiconductor device of claim 1, wherein the first transistor is configured to be part of a first integrated circuit comprising data-compression and AI-based inference functions, and
wherein the second transistor is configured to be part of a second integrated circuit comprising a signal-relaying function.

10. A semiconductor device comprising:
a first substrate comprising a first surface and a second surface opposite to the first surface;
a first transistor on the first surface of the first substrate and comprising a first source/drain pattern and a second source/drain pattern;
a first power line electrically connected to the first source/drain pattern, wherein the first power line is below the second surface of the first substrate;
a second substrate comprising:
a third surface, and
a fourth surface opposite to the third surface and facing the first surface of the first substrate;
a second transistor on the third surface of the second substrate and comprising a third source/drain pattern and a fourth source/drain pattern;
a second power line electrically connected to the third source/drain pattern and below the fourth surface of the second substrate;
a plurality of through via extending in a direction perpendicular to the first surface of the first substrate and extending into each of the first substrate and the second substrate; and
a first internal through via extending into the second substrate, wherein the first transistor and the second transistor are electrically connected through the first internal through via.

11. The semiconductor device of claim 10, wherein the plurality of through via comprises a first through via and a second through via,
wherein the first through via is electrically connected to the second power line, and
wherein the second through via is electrically connected to the fourth source/drain pattern of the second transistor.

12. The semiconductor device of claim 10, comprising a lower source/drain contact below the third source/drain pattern of the second transistor and extending into at least a portion of the second substrate,
wherein the lower source/drain contact is electrically connected to the third source/drain pattern and the second power line.

13. The semiconductor device of claim 10, comprising a second internal through via spaced apart from the first source/drain pattern of the first transistor and extending into the first substrate,
wherein the second internal through via is electrically connected to the first source/drain pattern and the first power line.

14. The semiconductor device of claim 10, wherein one of the plurality of through via is electrically connected to each of the first power line and the second power line.

15. The semiconductor device of claim 10, comprising:
an interlayer insulating layer below the second surface of the first substrate; and
a first lower pad and a second lower pad below a lower surface of the interlayer insulating layer,
wherein the plurality of through via comprise a first through via and a second through via,
wherein the first through via is electrically connected to the first lower pad, and
wherein the second through via is electrically connected to the second lower pad.

16. The semiconductor device of claim 15, wherein the first through via comprises a first portion in the interlayer insulating layer and a second portion extending into the first substrate and the second substrate, and
wherein an inclination of a sidewall of the first portion differs from an inclination of a sidewall of the second portion.

17. A semiconductor device comprising:
a first substrate comprising a first surface and a second surface opposite to the first surface;
a first transistor on the first surface of the first substrate and comprising a first source/drain pattern and a second source/drain pattern;
a first power line electrically connected to the first source/drain pattern and below the second surface of the first substrate;
a second substrate comprising:
a third surface, and
a fourth surface opposite to the third surface and facing the first surface of the first substrate;
a second transistor on the third surface of the second substrate and comprising a third source/drain pattern and a fourth source/drain pattern;
a first internal through via extending into the second substrate, wherein the second source/drain pattern of the first transistor and the fourth source/drain pattern of the second transistor are electrically connected through the first internal through via;
an interlayer insulating layer below the second surface of the first substrate;
a lower pad below a lower surface of the interlayer insulating layer; and
a first wiring structure in the interlayer insulating layer and electrically connected to the first power line and the lower pad.

18. The semiconductor device of claim 17, comprising a second power line below the fourth surface of the second substrate and electrically connected to the third source/drain pattern of the second transistor.

19. The semiconductor device of claim 17, comprising:
a lower source/drain contact extending into the first substrate and electrically connected to the first source/drain pattern of the first transistor and the first power line;
a second interlayer insulating layer on the third surface of the second substrate;
an upper pad on an upper surface of the second interlayer insulating layer; and
a second wiring structure on the second transistor, wherein the third source/drain pattern of the second transistor and the upper pad are electrically connected through the second wiring structure.

20. The semiconductor device of claim 17, comprising a through via extending into the first substrate and the second substrate and electrically connected to the first wiring structure.
